(19) United States
(12) Patent Application Publication
(10) Pub. No.: US 2026/0173661 A1
(43) Pub. Date: Jun. 18, 2026

(54) DISPLAY PANEL, METHOD FOR PREPARING DISPLAY PANEL, AND ELECTRONIC DEVICE

(71) Applicants: Hefei Visionox Technology Co., Ltd., Hefei (CN); Visionox Technology Inc., Kunshan (CN)

(72) Inventors: Zhao ZU, Hefei (CN); Cheng-Yi LIN, Hefei (CN); Yuan-Shih WANG, Hefei (CN); Bowen YANG, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/405,275

(22) Filed: Dec. 1, 2025

(30) Foreign Application Priority Data
Dec. 12, 2024 (CN) 202411841796.3

(51) Int. Cl. H10K 59/122; H10K 50/15; H10K 50/16; H10K 50/17; H10K 59/12; H10K 59/80

(52) U.S. Cl. CPC H10K 59/122; H10K 50/156; H10K 50/166; H10K 50/171; H10K 59/1201; H10K 59/80521; H10K 59/873

(57) ABSTRACT

The embodiments of the present application provide a display panel, a method for preparing a display panel, and an electronic device. In a first normal section that is perpendicular to a plane where a substrate is located and passes through a line connecting centroids of two adjacent isolation openings, a common layer includes a first end close to an isolation structure, the isolation structure includes a second end, and a first included angle is formed between a line connecting the first end and the second end on the same side of an isolation opening and the plane where the substrate is located, where the first included angle is greater than or equal to 50°and less than or equal to 80°. Such a design can prevent the common layer from overlapping with the isolation structure, thereby avoiding lateral leakage of a light-emitting device caused by the overlap between the two.

### CROSS-REFERENCE TO RELATED APPLICATIONS

The present application claims priority to Chinese Patent Application No. 202411841796.3 filed on Dec. 12, 2024, the disclosure of which is incorporated herein by reference in its entirety.

### FIELD

The present application relates to the field of display, and in particular to a display panel, a method for preparing a display panel, and an electronic device.

### BACKGROUND

With the development of display technology, Organic Light Emitting Diode (OLED) display panels are widely used due to advantages of thinness, high brightness, low power consumption, fast response, high clarity, and the like. During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, the process performance of current OLED display products still needs to be further improved.

### SUMMARY

In order to overcome the problem mentioned in the above background, the present application provides a display panel, a method for preparing a display panel, and an electronic device.

In one embodiment of the present application, a display panel is provided. The display panel includes:
a substrate;
an isolation structure arranged on a side of the substrate and enclosing isolation openings on the substrate; and
light-emitting devices at least partially located in the isolation openings, each light-emitting device including a light-emitting material layer and a first electrode;
where the light-emitting material layer includes a common layer, in a first normal section that is perpendicular to a plane where the substrate is located and passes through a line connecting centroids of two adjacent isolation openings, the common layer includes a first end close to the isolation structure, the isolation structure includes a second end, and an orthographic projection of the second end on the substrate corresponds to a contour line of an orthographic projection of an isolation opening on the substrate; and
in the first normal section, a first included angle is formed between a line connecting the first end and the second end on the same side of the isolation opening and the plane where the substrate is located, where the first included angle is greater than or equal to 50° and less than or equal to 80°.

In one embodiment of the present application, a method for preparing a display panel is further provided. The method includes:
providing a substrate;
fabricating an isolation structure and isolation openings on a side of the substrate; and
fabricating a light-emitting material layer and a first electrode of a light-emitting device in an isolation opening by means of evaporation, where the light-emitting material layer includes a common layer, and an evaporation angle of the common layer is greater than or equal to 50° and less than or equal to 80°.

In one embodiment of the present application, an electronic device is further provided. The electronic device includes a display panel in any one of embodiment or a display panel prepared by a method for preparing a display panel in the embodiments.

The embodiments of the present application provide a display panel, a method for preparing a display panel, and an electronic device. In the display panel, in the first normal section that is perpendicular to the plane where the substrate is located and passes through the line connecting the centroids of two adjacent isolation openings, the common layer includes the first end close to the isolation structure, the isolation structure includes the second end, and the first included angle is formed between the line connecting the first end and the second end on the same side of the isolation opening and the plane where the substrate is located, where the first included angle is greater than or equal to 50° and less than or equal to 80°. Such a design can prevent the common layer from overlapping with the isolation structure, thereby avoiding lateral leakage of the light-emitting device caused by the overlap between the two, and ensuring that the display panel has a good display effect.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope. Other related drawings can be obtained from these drawings

FIG. 1 illustrates a schematic distribution diagram of an isolation structure and isolation openings according to the embodiments;

FIG. 2 illustrates a first schematic diagram of a first normal section at position A1A1 in FIG. 1;

FIG. 3 illustrates a schematic diagram of orthographic projections of an isolation structure and a common layer according to the embodiments;

FIG. 4 illustrates a second schematic diagram of the first normal section at position A1A1 in FIG. 1;

FIG. 5 illustrates a first schematic diagram of a first normal section at position A2A2 in FIG. 1;

FIG. 6 illustrates a schematic diagram of a film layer structure of a light-emitting device;

FIG. 7 illustrates a schematic diagram of another film layer structure of a light-emitting device;

FIG. 8 illustrates a third schematic diagram of the first normal section at position A1A1 in FIG. 1;

FIG. 9 illustrates a fourth schematic diagram of the first normal section at position A1A1 in FIG. 1;

FIG. 10 illustrates a fifth schematic diagram of the first normal section at position A1A1 in FIG. 1;

FIG. 11 illustrates a second schematic diagram of the first normal section at position A2A2 in FIG. 1;

FIG. 12 illustrates a third schematic diagram of the first normal section at position A2A2 in FIG. 1;

FIG. 13 illustrates a schematic flowchart of a method for preparing a display panel according to the embodiments; and

FIG. 14 illustrates a process diagram corresponding to FIG. 13.

### DETAILED DESCRIPTION OF THE EMBODIMENTS

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

In the description of the present application, it should be noted that orientations or position relationships indicated by terms such as “upper” and “lower” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application.

Increasing the density (i.e. pixel density) of light-emitting devices in a display panel is an important way to improve the display effect. However, display panels currently made by using a fine metal mask (FMM) technology are unable to further increase the density of light-emitting devices due to limitations. The inventors have found, after long-term research, that in order to solve the problem that the density of light-emitting devices cannot be further increased, an isolation structure is provided in some display panels, and during the full-layer evaporation of light-emitting material layers and cathodes, the light-emitting material layers and the cathodes can be disconnected at the position of the isolation structure, and light-emitting devices of different colors can be formed in different isolation openings by means of multiple evaporation and multiple etching processes. The above process is referred to as patterning of the light-emitting devices.

In the above display panel, the inventors have found that there is a problem of poor display effect. In order to solve the above problem, the inventors have innovatively designed the following embodiments. The specific implementations of the present application will be described in detail below with reference to the accompanying drawings. It should be noted that the defects of the above solutions in the prior art are the results obtained by the inventors after practice and careful research. Therefore, the process of discovering the above problem and the solutions proposed in the following embodiments for the above problem should be regarded as the contributions made by the inventors to the present application during invention and creation, and should not be construed as the content that is well known in the art.

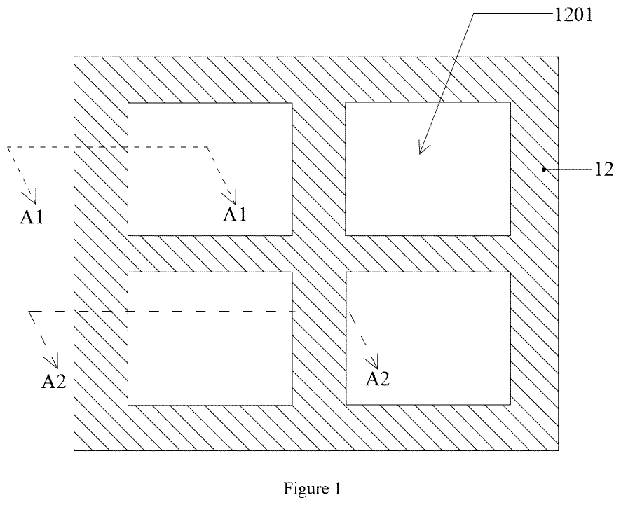

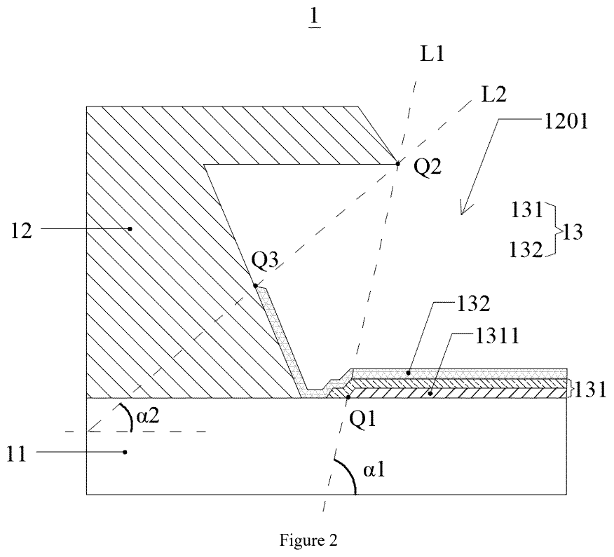

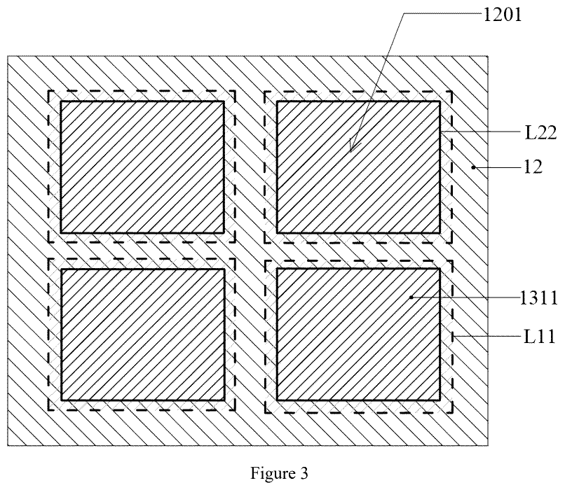

Referring to FIGS. 1, 2 and 3, FIG. 1 illustrates a schematic diagram of a regional distribution of a display panel according to the embodiments, FIG. 1 illustrates a schematic distribution diagram of an isolation structure and isolation openings according to the embodiments, FIG. 2 illustrates a schematic diagram of a first normal section at position AA in FIG. 1, and FIG. 3 illustrates a schematic diagram of orthographic projections of an isolation structure and a common layer according to the embodiments. In the embodiments, a display panel 1 includes a substrate 11, an isolation structure 12, and light-emitting devices 13. The substrate 11 has a multi-layer structure, and the substrate 11 includes at least a plurality of conductive layers and insulating layers located between adjacent conductive layers. A pixel circuit for providing driving signals for the light-emitting devices 13 is formed in the substrate 11. As an example, the conductive layers include metal conductive layers.

The isolation structure 12 is located on a side of the substrate 11 and encloses isolation openings 1201 on the substrate 11. The light-emitting devices 13 are at least partially located in the isolation openings 1201. Each light-emitting device 13 includes a light-emitting material layer 131 and a first electrode 132. The light-emitting material layer 131 includes a common layer 1311 with high conductivity. In a first normal section that is perpendicular to a plane where the substrate 11 is located and passes through a line connecting centroids of two adjacent isolation openings 1201, the common layer 1311 includes a first end Q1 close to the isolation structure 12, and an orthographic projection of the first end Q1 on the substrate 11 forms a contour line L11 of an orthographic projection of the common layer 1311 on the substrate 11. The isolation structure 12 includes a second end Q2, and an orthographic projection of the second end Q2 on the substrate 11 corresponds to a contour line L22 of an orthographic projection of an isolation opening 1201 on the substrate 11.

In the embodiments, in the first normal section, a first included angle α1 is formed between a line L1 connecting the first end Q1 and the second end Q2 on the same side of the isolation opening 1201 and the plane where the substrate 11 is located, where the first included angle α1 is greater than or equal to 50° and less than or equal to 80°. In the embodiments, unless otherwise specified, the plane where the substrate 11 is located refers to part of the plane where the substrate 11 is located that is on the side where the corresponding isolation opening 1201 is located. As an example, the first included angle α1 includes 50°, 51.2°, 57.4°, 62.6°, 68.2°, 74.6°, 79.1°, 84.5°, 88.7°, or 90°, etc.

The inventors have found that the above design can prevent the common layer 1311 from overlapping with the isolation structure 12, thereby avoiding lateral leakage of the light-emitting device 13 caused by the overlap between the two, and ensuring that the display panel 1 has a good display effect.

In the embodiments, the orthographic projection of the first end Q1 on the substrate 11 is located within the orthographic projection of the isolation structure 12 on the substrate 11, and the common layer 1311 does not overlap with the isolation structure 12. That is, the common layer 1311 and the isolation structure 12 are insulated from each other.

Further, the first electrode 132 may overlap with the isolation structure 12 on at least one side of the isolation opening 1201. Specifically, the first electrode 132 overlaps with a sidewall of the isolation structure 12 on at least one side of the isolation opening 1201, where the sidewall faces the corresponding isolation opening 1201.

Referring again to FIG. 2, in the first normal section, on an overlapping side of the first electrode 132 and the isolation structure 12, the first electrode 132 includes a third end Q3, and the third end Q3 overlaps with the sidewall of the isolation structure facing the corresponding isolation opening 1201. The third end Q3 corresponds to a highest overlapping point of the first electrode 132 on the sidewall of the isolation structure.

In the embodiments, a second included angle α2 is formed between a line L2 connecting the second end Q2 and the third end Q3 on the same overlapping side and the plane where the substrate 11 is located, where an angle difference between the first included angle α1 and the second included angle α2 is greater than or equal to 10°. As an example, the angle difference between the first included angle α1 and the second included angle α2 includes 10°, 12°, 15°, 20°, 22°, 28°, 35°, 40°, 42°or 45°, etc.

The inventors have found that when the angle difference between the first included angle α1 and the second included angle α2 meets the above condition, it can not only ensure that the common layer 1311 does not overlap with the isolation structure 12, but can also ensure effective overlapping between the first electrode 132 and the isolation structure 12. This allows the first electrodes 132 of different light-emitting devices 13 to be connected via the isolation structure 12, and the first electrodes 132 of the different light-emitting devices 13 have the same voltage, improving the overall display uniformity of the display panel 1.

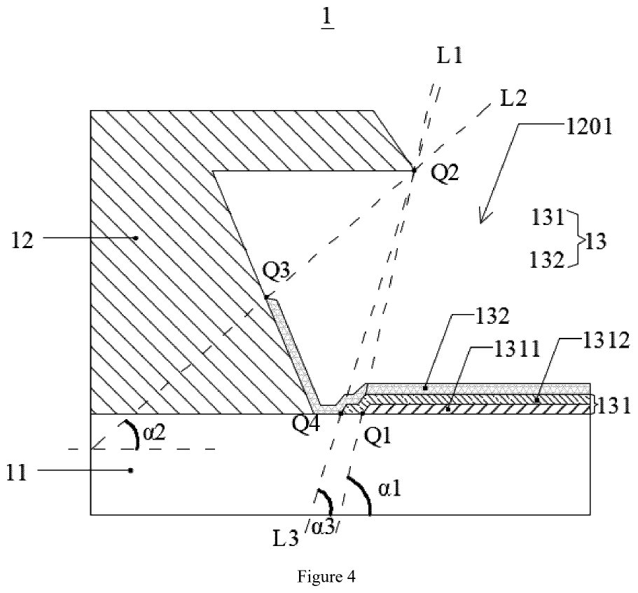

Referring to FIG. 4, in the embodiments, the light-emitting material layer 131 further includes an emission layer 1312. In the first normal section, on the overlapping side of the first electrode 132 and the isolation structure 12, the emission layer 1312 includes a fourth end Q4, and an orthographic projection of the fourth end Q4 on the substrate 11 corresponds to a contour line of an orthographic projection of the emission layer 1312 on the substrate 11. A third included angle α3 is formed between a line L3 connecting the second end Q2 and the fourth end Q4 on the same overlapping side and the plane where the substrate 11 is located, where an angle difference between the first included angle α1 and the third included angle α3 is less than or equal to 10°. As an example, the angle difference between the first included angle α1 and the third included angle α3 includes 0°, 1°, 2.5°, 4.5°, 5.3°, 6.4°, 7.5°, 8°, 9.5°or 10°, etc.

The inventors have found that when the angle difference between the first included angle α1 and the third included angle α3 meets the above condition, it can ensure that the light-emitting device 13 has a large light-emitting area, thereby improving the display brightness of the display panel.

In the embodiments, the first included angle α1, the third included angle α3, and the second included angle α2 decrease in succession, that is, the first included angle α1 is the largest, the third included angle α3 is the second largest, and the second included angle α2 is the smallest.

Referring again to FIG. 4, in one embodiment, the orthographic projection of the fourth end Q4 on the substrate 11 is located between the orthographic projection of the first end Q1 on the substrate 11 and the orthographic projection of the third end Q3 on the substrate 11. That is, the orthographic projection of the first end Q1 on the substrate 11 is located on one side of the orthographic projection of the fourth end Q4 on the substrate 11, and the orthographic projection of the third end Q3 on the substrate 11 is located on the other side of the orthographic projection of the fourth end Q4 on the substrate 11.

Further, referring to FIG. 5, the display panel 1 further includes a pixel defining layer 14 located on the substrate 11. The isolation structure 12 is positioned on a side of the pixel defining layer 14 away from the substrate 11, the pixel defining layer 14 includes pixel openings 1401, and the pixel openings 1401 are in communication with the isolation openings 1201. As an example, an orthographic projection of a pixel opening 1401 on the substrate 11 is located within the orthographic projection of the isolation opening 1201 on the substrate 11. At least part of the light-emitting device 13 is located in the pixel opening 1401.

Further, the light-emitting device 13 further includes a second electrode 133 located on a side of the pixel defining layer 14 facing the substrate 11, the pixel opening 1401 exposes part of the second electrode 133, and the second electrode 133, the light-emitting material layer 131, and the first electrode 132 are stacked in a direction away from the substrate 11 (a Z direction in the figure). The second electrode 133 may be connected to the pixel circuit in the substrate 11, and the pixel circuit in the substrate 11 provides a driving signal for the light-emitting device 13. The second electrode 133 may serve as an anode of the light-emitting device 13, and the first electrode 132 may serve as a cathode of the light-emitting device 13.

In the embodiments, the light-emitting device 13 may be a single-layer device or a stacked device. That is, the light-emitting material layer 131 of the light-emitting device 13 may include only one emission layer 1312, or at least two emission layers 1312.

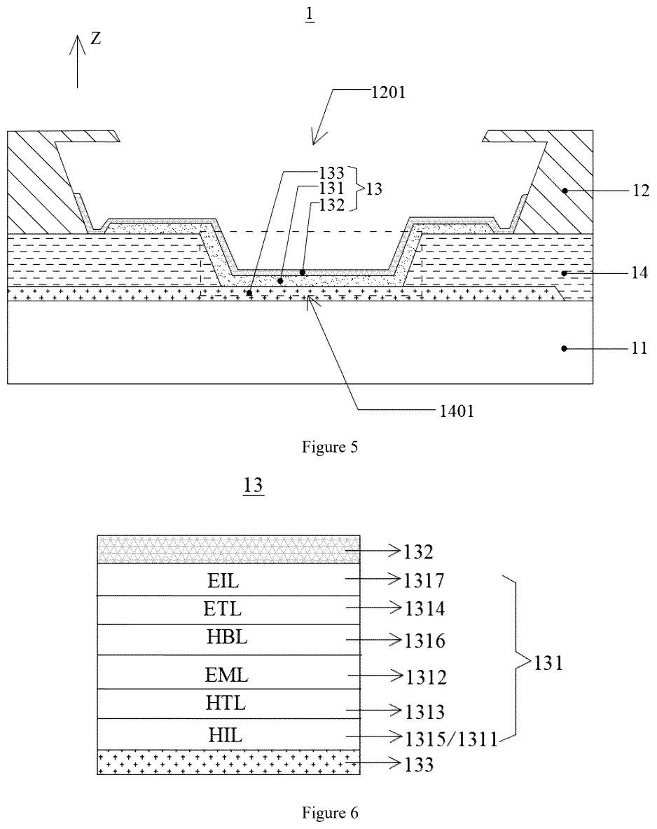

In one embodiment, referring to FIG. 6, the light-emitting material layer 131 includes one emission layer 1312, and the light-emitting material layer 131 includes a hole transport layer (HTL) 1313, the emission layer 1312 (EML), and an electron transport layer (ETL) 1314 that are sequentially stacked in the direction away from the substrate 11.

Further, referring to FIG. 6, the light-emitting material layer 131 further includes a hole injection layer (HIL) 1315, a hole block layer (HBL) 1316, and an electron injection layer (EIL) 1317. The hole injection layer 1315 is located on a side of the hole transport layer 1313 away from the emission layer 1312. That is, the hole injection layer 1315 is located between the hole transport layer 1313 and the second electrode 133. The hole block layer 1316 is located between the emission layer 1312 and the electron transport layer 1314. The electron injection layer 1317 is located on a side of the electron transport layer 1314 away from the emission layer 1312. That is, the electron injection layer 1317 is located between the electron transport layer 1314 and the first electrode 132.

In this implementation, the common layer 1311 includes the hole injection layer 1315.

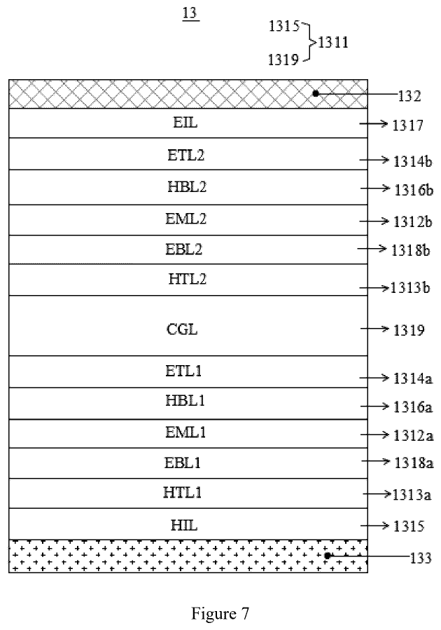

In one embodiment, referring to FIG. 7, the light-emitting material layer 131 includes at least two emission layers 1312. An example in which the light-emitting material layer 131 includes two emission layers 1312 is described below.

The light-emitting material layer 131 includes a hole injection layer 1315, a first hole transport layer 1313a, a first electron block layer 1318a, a first emission layer 1312a, a first hole block layer 1316a, a first electron transport layer 1314a, a charge generation layer 1319, a second hole transport layer 1313b, a second electron block layer 1318b, a second emission layer 1312b, a second hole block layer 1316b, a second electron transport layer 1314b, and an electron injection layer 1317 that are sequentially stacked in the direction away from the substrate 11.

In this implementation, the common layer 1311 includes the hole injection layer 1315 and the charge generation layer 1319.

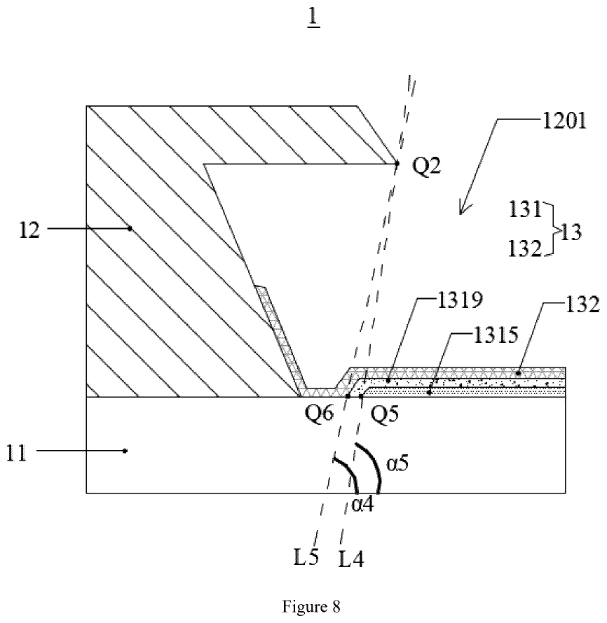

Referring to FIG. 8, in the first normal section, on the overlapping side of the first electrode 132 and the isolation structure 12, the hole injection layer 1315 includes a fifth end Q5, the charge generation layer 1319 includes a sixth end Q6, a fourth included angle α4 is formed between a line L4 connecting the second end Q2 and the fifth end Q5 on the same overlapping side and the plane where the substrate 11 is located, and a fifth included angle α5 is formed between a line L5 connecting the second end Q2 and the sixth end Q6 on the same overlapping side and the plane where the substrate 11 is located, where the fourth included angle α4 and the fifth included angle α5 are equal or unequal.

In this implementation, to insulate both the hole injection layer 1315 and the charge generation layer 1319 from the isolation structure 12, an angle difference between the fourth included angle α4 and the fifth included angle α5 is less than or equal to 1°. As an example, the angle difference between the fourth included angle α4 and the fifth included angle α5 includes 0°, 0.05°, 0.1°, 0.15°, 0.25°, 0.4°, 0.65°, 0.82°, 0.95°, or 1°.

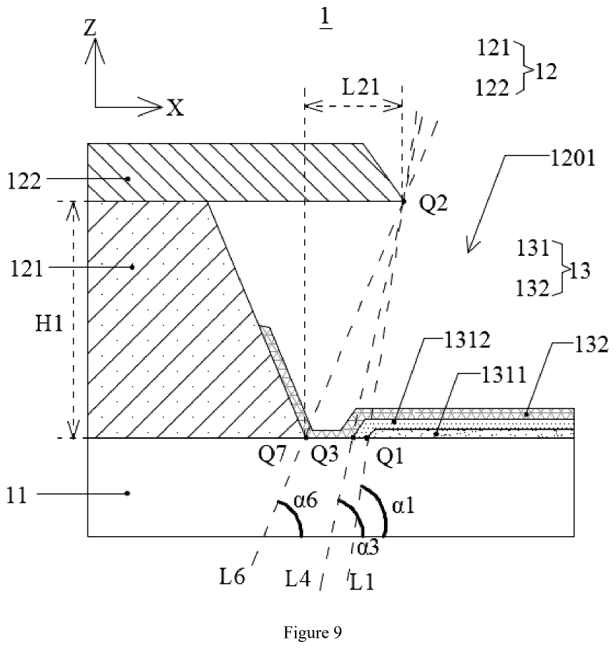

In the embodiments, referring to FIG. 9, the isolation structure 12 includes a first isolation portion 121 and a second isolation portion 122 that are stacked, the second isolation portion 122 is arranged on a side of the first isolation portion 121 away from the substrate 11, and an orthographic projection of the first isolation portion 121 on the substrate 11 is located within an orthographic projection of the second isolation portion 122 on the substrate 11. In the first normal section, the isolation structure 12 may be T-shaped.

In the first normal section, the second end Q2 is an end of the second isolation portion 122 that is away from the first isolation portion 121 and faces the isolation opening 1201, and the first electrode 132 overlaps with a sidewall of the first isolation portion 121 facing the corresponding isolation opening 1201.

Referring again to FIG. 9, in a direction perpendicular to the plane where the substrate 11 is located (the Z direction in the figure), the first isolation portion 121 has a first height H1. In a direction toward the corresponding isolation opening 1201 (an X direction in the figure), the orthographic projection of the second isolation portion 122 on the substrate 11 has a first extension length L21 relative to the orthographic projection of the first isolation portion 121 on the substrate 11, and an arctangent value of a ratio of the first height H1 to the first extension length L21 is less than the first included angle α1, i.e., arctan(H1/L21)<α1. Such a design can prevent the common layer 1311 from overlapping with the first isolation portion 121.

Further, in the first normal section, the first isolation portion 121 may be in the shape of a regular trapezoid, and the first isolation portion 121 includes a seventh end Q7. The seventh end Q7 is an end of the first isolation portion 121 on a side thereof facing the substrate 11 and close to the corresponding isolation opening 1201.

A sixth included angle α6 is formed between a line L6 connecting the seventh end Q7 and the second end Q2 on the same side of the isolation opening 1201 and the plane where the substrate 11 is located, where the sixth included angle α6 is less than the first included angle α1. Such a design can prevent the common layer 1311 in the light-emitting material layer 131 from overlapping with the second isolation portion 122, thereby avoiding lateral leakage of the light-emitting device 13.

In one embodiment, the emission layer 1312 may be in contact with the second isolation portion 122. Specifically, the emission layer 1312 overlaps with the second isolation portion 122 or their boundaries are flush. In this case, the sixth included angle α6 is greater than or equal to the third included angle α3. The emission layer 1312 may also not be in contact with the second isolation portion 122. In this case, the sixth included angle α6 is less than the third included angle α3.

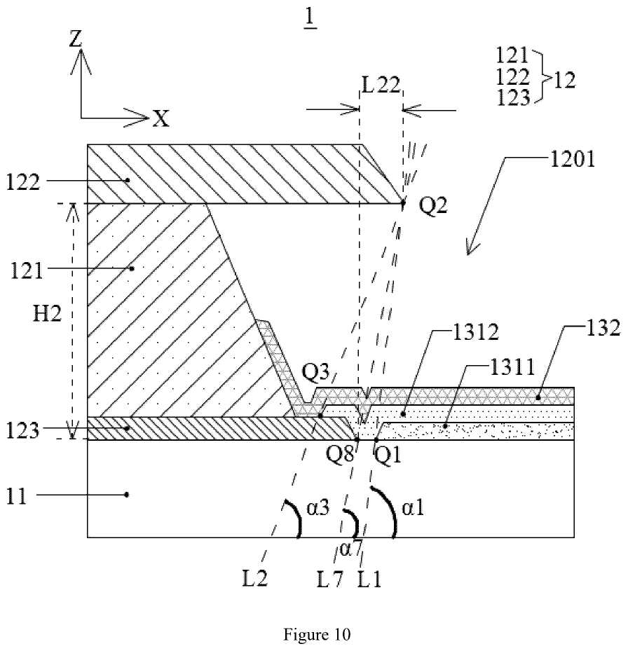

Further, referring to FIG. 10, the isolation structure 12 further includes a third isolation portion 123, the third isolation portion 123, the first isolation portion 121, and the second isolation portion 122 are sequentially stacked in the direction away from the substrate 11, and the orthographic projection of the first isolation portion 121 on the substrate 11 is located within an orthographic projection of the third isolation portion 123 on the substrate 11.

In one embodiment, the orthographic projection of the third isolation portion 123 on the substrate 11 is located within the orthographic projection of the second isolation portion 122 on the substrate 11, and in the first normal section, the isolation structure 12 may be I-shaped.

Referring again to FIG. 10, the third isolation portion 123 includes an eighth end Q8 close to the corresponding isolation opening 1201, and a seventh included angle α7 is formed between a line L7 connecting the eighth end Q8 and the second end Q2 on the same side of the isolation opening 1201 and the plane where the substrate 11 is located, where the seventh included angle α7 is less than the first included angle α1. Such a design can prevent the common layer 1311 in the light-emitting material layer 131 from overlapping with the third isolation portion 123, thereby avoiding lateral leakage of the light-emitting device 13.

In one embodiment, the emission layer 1312 may be in contact with the third isolation portion 123. Specifically, the emission layer 1312 overlaps with the third isolation portion 123 or their boundaries are flush. In this case, the seventh included angle α7 is greater than or equal to the third included angle α3. The emission layer 1312 may also not be in contact with the third isolation portion 123. In this case, the seventh included angle α7 is less than the third included angle α3.

In the embodiments, the first electrode 132 also overlaps with the third isolation portion 123.

Referring again to FIG. 10, in the direction perpendicular to the plane where the substrate 11 is located (the Z direction in the figure), a total height of the first isolation portion 121 and the third isolation portion 123 is a second height H2. In the direction toward the corresponding isolation opening 1201 (X direction in the figure), the orthographic projection of the second isolation portion 122 on the substrate 11 has a second extension length L22 relative to an orthographic projection of the third isolation portion 123 on the substrate 11, and an arctangent value of a ratio of the second height H2 to the second extension length L22 is less than the first included angle α1, i.e., arctan(H2/L22)<α1. Such a design can prevent the common layer 1311 from overlapping with the third isolation portion 123.

In the embodiments, a material of the first isolation portion 121 includes aluminum, silver, or copper, a material of the second isolation portion 122 includes titanium or molybdenum, and a material of the third isolation portion 123 includes molybdenum or titanium.

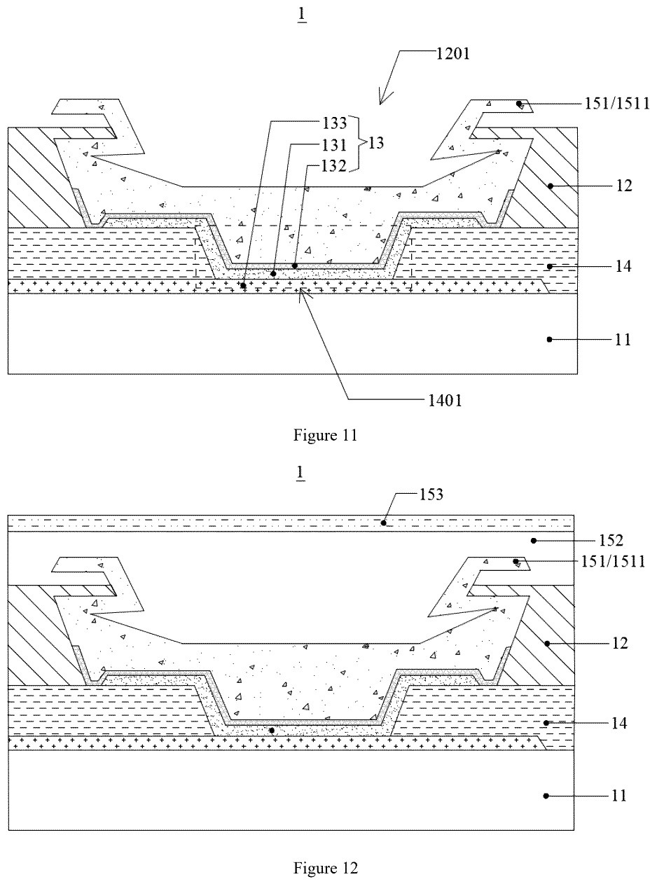

Further, referring to FIG. 11, in the embodiments, the display panel 1 further includes a first encapsulation layer 151. The first encapsulation layer 151 includes a plurality of encapsulation units 1511 for encapsulating different light-emitting devices 13. Each encapsulation unit 1511 is located on a side of the light-emitting device 13 away from the substrate 11, and extends from a surface of the light-emitting device 13 to a side of the isolation structure 12 away from the substrate 11 along the sidewall of the isolation structure 12 facing the isolation opening 1201. In one embodiment, two adjacent encapsulation units 1511 for encapsulating light-emitting devices 13 of different colors are disconnected on the side of the isolation structure 12 away from the substrate 11, and a gap exists between the encapsulation unit 1511 and the isolation structure 12 on the side of the isolation structure 12 away from the substrate 11. Two adjacent encapsulation units 1511 for encapsulating light-emitting devices 13 of the same color are connected to each other on the side of the isolation structure 12 away from the substrate 11.

Further, referring to FIG. 12, the display panel 1 further includes a second encapsulation layer 152. The second encapsulation layer 152 is located on a side of the encapsulation unit 1511 away from the substrate 11, and the second encapsulation layer 152 covers at least the encapsulation units 1511. In one embodiment, the second encapsulation layer 152 has a flat surface on a side thereof away from the substrate 11.

Further, the display panel 1 further includes a third encapsulation layer 153. The third encapsulation layer 153 is located on the side of the second encapsulation layer 152 away from the substrate 11.

In one embodiment, materials of the first encapsulation layer 151 and the third encapsulation layer 153 include inorganic encapsulation materials, and a material of the second encapsulation layer 152 includes an organic encapsulation material. That is, the first encapsulation layer 151 and the third encapsulation layer 153 are inorganic encapsulation layers, and the second encapsulation layer 152 is an organic encapsulation layer. For example, the first encapsulation layer 151 and the third encapsulation layer 153 may be formed by means of chemical vapor deposition (CVD), and the second encapsulation layer 152 may be formed by means of ink-jet printing (IJP).

It should be understood that the display panel 1 may further include film layers such as a touch-control function layer, an optical adhesive layer, a polarizer and a cover plate that are sequentially stacked on a side of the third encapsulation layer 153 away from the substrate 11. The above film layers are conventional film layers of the display panel and will not be repeated here.

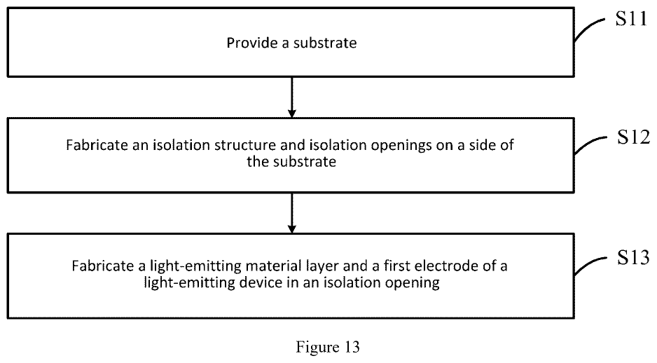

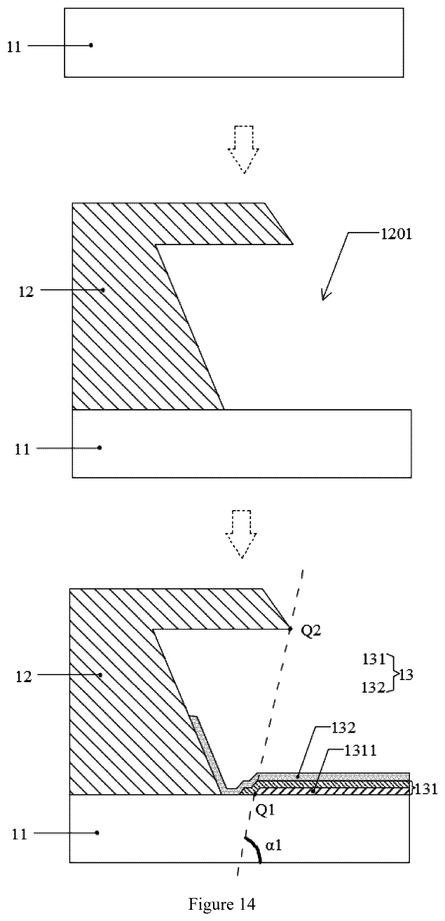

The embodiments further provide a method for preparing a display panel. Referring to FIGS. 13 and 14, FIG. 13 illustrates a schematic flowchart of the method for preparing a display panel according to the embodiments, and FIG. 14 illustrates a process diagram corresponding to FIG. 13. The method for preparing a display panel according to the embodiments will be described in detail below with reference to FIGS. 13 and 14.

In step S11, a substrate 11 is provided.

In the embodiments, the substrate 11 has a multi-layer structure, and the substrate 11 includes at least a plurality of conductive layers and insulating layers located between adjacent conductive layers. A pixel circuit 111 for providing driving signals for the light-emitting devices is formed in the substrate 11. As an example, the conductive layers include metal conductive layers.

In step S12, an isolation structure 12 and isolation openings 1201 are fabricated on a side of the substrate 11.

Specifically, an isolation structure material layer may be fabricated on the substrate 11, and the isolation structure material layer is patterned to obtain the isolation structure 12 and the isolation openings 1201.

In step S13, a light-emitting material layer 131 and a first electrode 132 of a light-emitting device 13 is fabricated in an isolation opening 1201.

The light-emitting material layer 131 includes a common layer 1311 with high conductivity. In step S13, when fabricating the common layer 1311 by evaporation, an evaporation angle of the common layer 1311 is controlled between 50° and 80°. That is, the evaporation angle of the common layer 1311 is greater than or equal to 50° and less than or equal to 80°. The common layer 1311 formed by evaporation at the above-described evaporation angle satisfies the following conditions: in a first normal section that is perpendicular to a plane where the substrate 11 is located and passes through a line connecting centroids of two adjacent isolation openings 1201, the common layer 1311 includes a first end Q1 close to the isolation structure 12, and an orthographic projection of the first end Q1 on the substrate 11 forms a contour line L11 of an orthographic projection of the common layer 1311 on the substrate 11; the isolation structure 12 includes a second end Q2, and an orthographic projection of the second end Q2 on the substrate 11 corresponds to a contour line L22 of an orthographic projection of the isolation opening 1201 on the substrate 11; and a first included angle α1 is formed between a line L1 connecting the first end Q1 and the second end Q2 on the same side of the isolation opening 1201 and the plane where the substrate 11 is located, where the first included angle α1 is greater than or equal to 50° and less than or equal to 80°.

The embodiments of the present application further provide an electronic device. The electronic device includes a display panel according to the above embodiments, or includes a display panel prepared by a method for preparing a display panel according to the above embodiments. The electronic device may include devices with a display function such as a smart phone, a tablet computer, a vehicle-mounted display device, a smart wearable device, a television, and a laptop computer.

The embodiments of the present application provide a display panel, a method for preparing a display panel, and an electronic device. In the display panel, in the first normal section that is perpendicular to the plane where the substrate is located and passes through the line connecting the centroids of two adjacent isolation openings, the common layer includes the first end close to the isolation structure, the isolation structure includes the second end, and the first included angle is formed between the line connecting the first end and the second end on the same side of the isolation opening and the plane where the substrate is located, where the first included angle is greater than or equal to 50° and less than or equal to 80°. Such a design can prevent the common layer from overlapping with the isolation structure, thereby avoiding lateral leakage of the light-emitting device caused by the overlap between the two, and ensuring that the display panel has a good display effect.

The foregoing descriptions are merely some embodiments of the present application, but are not intended to limit the present application. The present application may have various modifications and variations. Any modifications, equivalent substitutions, improvements, etc. made within the spirit and principle of the present application should fall within the scope of protection of the present application.

1. A display panel, comprising:
a substrate;
an isolation structure arranged on a side of the substrate and enclosing isolation openings on the substrate; and
light-emitting devices at least partially located in the isolation openings, each light-emitting device comprising a light-emitting material layer and a first electrode; wherein the light-emitting material layer comprises a common layer, in a first normal section that is perpendicular to a plane where the substrate is located and passes through a line connecting centroids of two adjacent isolation openings, the common layer comprises a first end close to the isolation structure, the isolation structure comprises a second end, and an orthographic projection of the second end on the substrate corresponds to a contour line of an orthographic projection of an isolation opening on the substrate; and
in the first normal section, a first included angle is formed between a line connecting the first end and the second end on the same side of the isolation opening and the plane where the substrate is located, wherein the first included angle is greater than or equal to 50° and less than or equal to 80°.

2. The display panel according to claim 1, wherein an orthographic projection of the first end on the substrate is located within the orthographic projection of the isolation structure on the substrate; and
the common layer is insulated from the isolation structure.

3. The display panel according to claim 1, wherein the first electrode overlaps with the isolation structure on at least one side of the isolation opening;
in the first normal section, on an overlapping side of the first electrode and the isolation structure, the first electrode comprises a third end, and the third end overlaps with a sidewall of the isolation structure facing the corresponding isolation opening; and a second included angle is formed between a line connecting the second end and the third end on the same overlapping side and the plane where the substrate is located, wherein an angle difference between the first included angle and the second included angle is greater than or equal to 10°.

4. The display panel according to claim 3, wherein the light-emitting material layer further comprises an emission layer, and
in the first normal section, on the overlapping side of the first electrode and the isolation structure, the emission layer comprises a fourth end, and a third included angle is formed between a line connecting the second end and the fourth end on the same overlapping side and the plane where the substrate is located, wherein an angle difference between the first included angle and the third included angle is less than or equal to 10°.

5. The display panel according to claim 4, wherein the first included angle, the third included angle, and the second included angle decrease in succession.

6. The display panel according to claim 4, wherein an orthographic projection of the fourth end on the substrate is located between an orthographic projection of the first end on the substrate and an orthographic projection of the third end on the substrate.

7. The display panel according to claim 1, further comprises a pixel defining layer; wherein the pixel defining layer is located on the substrate, the isolation structure is positioned on a side of the pixel defining layer away from the substrate, the pixel defining layer comprises pixel openings, and the pixel openings are in communication with the isolation openings;
at least part of the light-emitting device is located in a pixel opening; and the light-emitting device further comprises a second electrode located on a side of the pixel defining layer facing the substrate, the pixel opening exposes part of the second electrode, and the second electrode, the light-emitting material layer, and the first electrode are stacked in a direction away from the substrate.

8. The display panel according to claim 7, wherein the light-emitting material layer comprises one emission layer, and the light-emitting material layer comprises a hole transport layer, the emission layer, and an electron transport layer that are sequentially stacked in the direction away from the substrate;
the light-emitting material layer further comprises a hole injection layer, a hole block layer, and an electron injection layer, the hole injection layer is located on a side of the hole transport layer away from the emission layer, the hole block layer is located between the emission layer and the electron transport layer, and the electron injection layer is located on a side of the electron transport layer away from the emission layer; and
the common layer comprises the hole injection layer.

9. The display panel according to claim 7, wherein the light-emitting material layer comprises at least two emission layers;
the light-emitting material layer comprises a hole injection layer, a first hole transport layer, a first electron block layer, a first emission layer, a first hole block layer, a first electron transport layer, a charge generation layer, a second hole transport layer, a second electron block layer, a second emission layer, a second hole block layer, a second electron transport layer, and an electron injection layer that are sequentially stacked in the direction away from the substrate; and
the common layer comprises the hole injection layer and the charge generation layer.

10. The display panel according to claim 9, wherein in the first normal section, on an overlapping side of the first electrode and the isolation structure, the hole injection layer comprises a fifth end, the charge generation layer comprises a sixth end, a fourth included angle is formed between a line connecting the second end and the fifth end on the same overlapping side and the plane where the substrate is located, and a fifth included angle is formed between a line connecting the second end and the sixth end on the same overlapping side and the plane where the substrate is located, wherein the fourth included angle and the fifth included angle are equal or unequal.

11. The display panel according to claim 10, wherein an angle difference between the fourth included angle and the fifth included angle is less than or equal to 1°.

12. The display panel according to claim 4, wherein the isolation structure comprises a first isolation portion and a second isolation portion that are stacked, the second isolation portion is arranged on a side of the first isolation portion away from the substrate, and an orthographic projection of the first isolation portion on the substrate is located within an orthographic projection of the second isolation portion on the substrate;
in the first normal section, the second end is an end of the second isolation portion that is away from the first isolation portion and faces the isolation opening; and
the first electrode overlaps with a sidewall of the first isolation portion facing the corresponding isolation opening.

13. The display panel according to claim 12, wherein in a direction perpendicular to the plane where the substrate is located, the first isolation portion has a first height, in a direction toward the corresponding isolation opening, the orthographic projection of the second isolation portion on the substrate has a first extension length relative to the orthographic projection of the first isolation portion on the substrate, and an arctangent value of a ratio of the first height to the first extension length is less than the first included angle.

14. The display panel according to claim 13, wherein in the first normal section, the first isolation portion is in the shape of a regular trapezoid, and the first isolation portion comprises a seventh end, wherein the seventh end is an end of the first isolation portion on a side thereof facing the substrate and close to the corresponding isolation opening; and
a sixth included angle is formed between a line connecting the seventh end and the second end on the same side of the isolation opening and the plane where the substrate is located, wherein the sixth included angle is less than the first included angle.

15. The display panel according to claim 14, wherein
the isolation structure further comprises a third isolation portion, the third isolation portion, the first isolation portion, and the second isolation portion are sequentially stacked in the direction away from the substrate, and the orthographic projection of the first isolation portion on the substrate is located within an orthographic projection of the third isolation portion on the substrate;
the orthographic projection of the third isolation portion on the substrate is located within the orthographic projection of the second isolation portion on the substrate; and
the third isolation portion comprises an eighth end close to the corresponding isolation opening, and a seventh included angle is formed between a line connecting the eighth end and the second end on the same side of the isolation opening and the plane where the substrate is located, wherein the seventh included angle is less than the first included angle.

16. The display panel according to claim 15, wherein the first electrode overlaps with the third isolation portion; and
in the direction perpendicular to the plane where the substrate is located, a total height of the first isolation portion and the third isolation portion is a second height, in the direction toward the corresponding isolation opening, the orthographic projection of the second isolation portion on the substrate has a second extension length relative to the orthographic projection of the third isolation portion on the substrate, and an arctangent value of a ratio of the second height to the second extension length is less than the first included angle.

17. The display panel according to claim 15, wherein a material of the first isolation portion comprises aluminum, silver, or copper, a material of the second isolation portion comprises titanium or molybdenum, and a material of the third isolation portion comprises molybdenum or titanium.

18. The display panel according to claim 1, wherein the display panel further comprises a first encapsulation layer, the first encapsulation layer comprises a plurality of encapsulation units, and different encapsulation units encapsulate the light-emitting devices in different isolation openings;
the display panel further comprises a second encapsulation layer, the second encapsulation layer are located on a side of an encapsulation unit away from the substrate, and the second encapsulation layer covers at least the encapsulation units;
the second encapsulation layer has a flat surface on a side thereof away from the substrate;
the display panel further comprises a third encapsulation layer arranged on the side of the second encapsulation layer away from the substrate; and
the first encapsulation layer and the third encapsulation layer are inorganic encapsulation layers, and the second encapsulation layer is an organic encapsulation layer.

19. A method for preparing a display panel, the method comprising:
providing a substrate;
fabricating an isolation structure and isolation openings on a side of the substrate; and
fabricating a light-emitting material layer and a first electrode of a light-emitting device in an isolation opening by means of evaporation, wherein the light-emitting material layer comprises a common layer, and an evaporation angle of the common layer is greater than or equal to 50° and less than or equal to 80°.

20. An electronic device, comprising:
a display panel, comprising:
a substrate;
an isolation structure arranged on a side of the substrate and enclosing isolation openings on the substrate; and
light-emitting devices at least partially located in the isolation openings, each light-emitting device comprising a light-emitting material layer and a first electrode;
wherein the light-emitting material layer comprises a common layer, in a first normal section that is perpendicular to a plane where the substrate is located and passes through a line connecting centroids of two adjacent isolation openings, the common layer comprises a first end close to the isolation structure, the isolation structure comprises a second end, and an orthographic projection of the second end on the substrate corresponds to a contour line of an orthographic projection of an isolation opening on the substrate; and
in the first normal section, a first included angle is formed between a line connecting the first end and the second end on the same side of the isolation opening and the plane where the substrate is located, wherein the first included angle is greater than or equal to 50° and less than or equal to 80°.
